(19) United States
(12) Patent Application Publication
(10) Pub. No.: US 2023/0255121 A1
(43) Pub. Date: Aug. 10, 2023

(54) PERPENDICULAR MAGNETIC TUNNEL JUNCTION WITH MULTI-INTERFACE FREE LAYER FOR MAGNETOELECTRIC DEVICES

(71) Applicant: Arizona Board of Regents on Behalf of the University of Arizona, Tucson, AZ (US)

(72) Inventors: Weigang Wang, Tucson, AZ (US); Pravin Khanal, Tucson, AZ (US)

(21) Appl. No.: 17/667,973

(22) Filed: Feb. 9, 2022

(51) Int. Cl. H01L 43/10; H01L 43/02

(52) U.S. Cl. CPC H01L 43/10; H01L 43/02

(57) ABSTRACT

A magnetic memory cell can include a reference ferromagnetic layer; a barrier layer on the reference ferromagnetic layer; a multiple-interface free layer (MIFL) on the barrier layer; and a capping layer on the MIFL. The MIFL has at least three coupled sublayers, providing at least four interfaces for the MIFL.

### STATEMENT REGARDING FEDERALLY SPONSORED RESEARCH

This invention was made with government support under Grant Nos. 1554011 and 1905783 awarded by NSF, and FA8650-18-2-7868 awarded by USAF/AFOSR. The government has certain rights in the invention.

### BACKGROUND

Magnetoresistive random-access memory (MRAM) is an alternative memory technology to FLASH random-access memory and dynamic random-access memory (DRAM) that relies on magnetic storage elements rather than electrical charge to store a value. As the values are stored magnetically, the values can be said to be non-volatile - at minimum, because magnetic fields are substantially harder to disrupt than current flows, which can be disrupted by extended or even short power outages. Specifically, magnetoelectric-based memory cells are composed of two magnetic elements that can separately store a spin direction. When the two magnetic elements have the same alignment, there is a low resistance through the cell, which can be interpreted as a 1. Conversely, if the two magnetic elements have antiparallel alignment, the resistance of the cell will be appreciable and thus a value of 0 can be interpreted.

Historically, MRAM has been sidelined in favor of other memory technologies in part due to a tradeoff between size and performance. Other forms of memory such as DRAM are more compact. MRAM cells, on the other hand, often suffer from performance issues at a low size – if there is not enough magnetic material, there can be issues of maintaining a spin state or even insufficiently differentiating between a value of one and a value of zero.

### BRIEF SUMMARY

A perpendicular magnetic tunnel junction (pMTJ) with a multi-interface free layer is described which is suitable for magnetoelectric devices, including implementing magnetoelectric-based memory. The multi-interface free layer offers the ability to select for particular physical advantages while maintaining a similarly small profile when compared against state-of-the-art magnetic tunnel junctions. By making the free layer composed of a variety of materials – rather than a monolithic ferromagnetic layer - different materials with different physical advantages, such as high resolution between zero and one and high switching speeds –can be used together to optimize characteristics.

A magnetic memory cell can include a reference ferromagnetic layer; a barrier layer on the reference ferromagnetic layer; a multiple-interface free layer (MIFL) on the barrier layer, and a capping layer on the MIFL. The MIFL is formed of at least three coupled sublayers, including a first sublayer and at least two other sublayers. The other sublayers on the first sublayer include at least one different material than the first sublayer.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1 illustrates an example perpendicular magnetic tunnel junction (pMTJ) cell.

FIG. 2 illustrates an array of pMTJ cells arranged for a memory application.

FIGS. 3A and 3B illustrate example configurations of a pMTJ with a multi-interface free layer (MIFL).

FIG. 4A shows a representation of a multiple-interface free layer (MIFL) having N = 4 and alternating sublayers of CoFeB and MgO.

FIGS. 4B-4G show experimental results for MIFLs with MgO as the coupling layer.

FIG. 5A shows a representation of a MIFL having N= 4 and alternating sublayers of CoFeB and Ta.

FIGS. 5B-5I show experimental results of performance of an MIFL of the structure of CoFeB/Ta/CoFeB as shown in FIG. 5A.

FIG. 6A shows a representation of a MIFL having N = 6 with sublayers of CoFeB, Mo, and MgO.

FIGS. 6B-6H show experimental results of performance of an MIFL of the structure of CoFeB/Mo/CoFeB/MgO/CoFeB as shown in FIG. 6A.

FIG. 6I shows an HRTEM image of the pMTJ with MIFL as shown in FIG. 6A.

### DETAILED DESCRIPTION

Perpendicular magnetic tunnel junctions (pMTJs) with a multi-interface free layer are described. The described structures are suitable for magnetoelectric devices, including implementing magnetoelectric-based memory. The multi-interface free layer offers the ability to select for particular physical advantages at a granular level while maintaining a similarly small profile when compared against state-of-the-art magnetic tunnel junctions. By making the free layer composed of a variety of materials – rather than a monolithic ferromagnetic layer – different materials with different physical advantages, such as high resolution between zero and one and high switching speeds – can be used together to optimize characteristics.

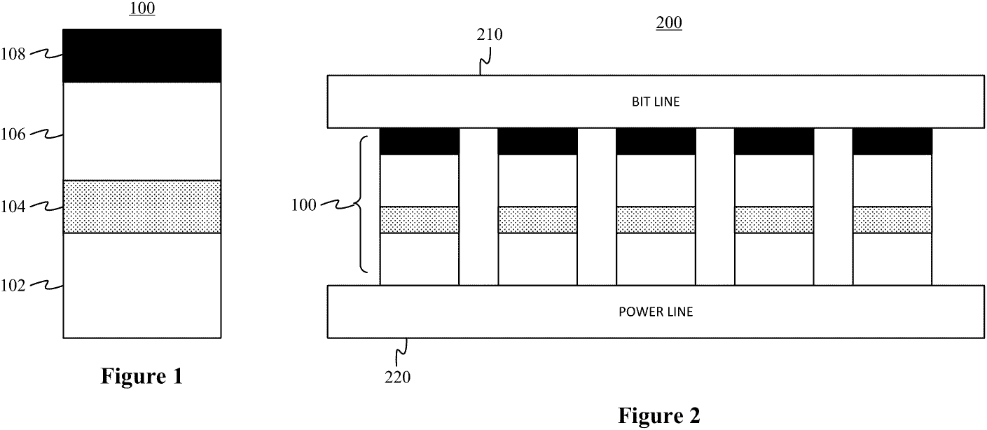

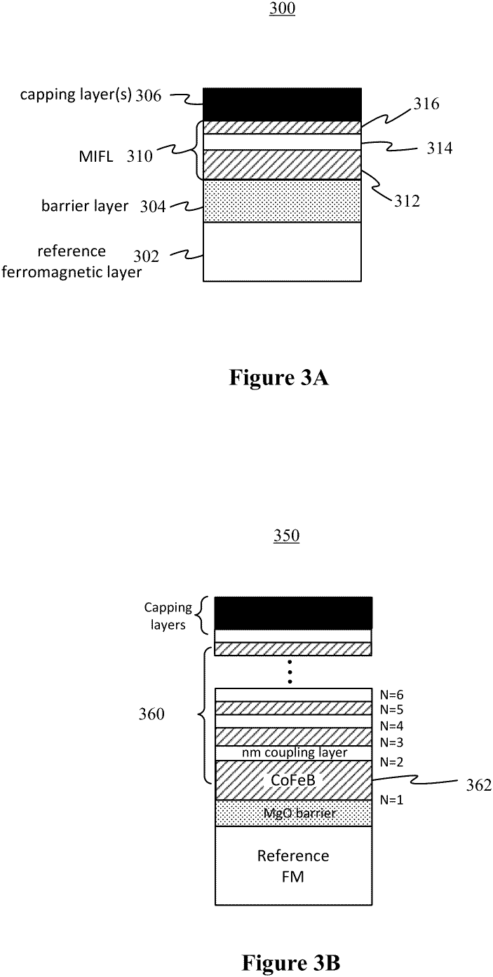

FIG. 1 illustrates an example perpendicular magnetic tunnel junction (pMTJ) cell. A pMTJ cell 100 can include four layers of material that are fused together: a reference ferromagnetic layer 110, a barrier layer 120, a free layer 130, and a capping layer 140. The reference ferromagnetic layer 110 can be composed of a ferromagnetic material. As the name implies, the reference ferromagnetic layer 110 can have a magnetic spin that is less likely to change or even have a fixed magnetic direction. The barrier layer 120 can be composed of a nonmagnetic material and serve to magnetically and physically separate the free layer 130 from the reference ferromagnetic layer 110. The free layer 130 can also be composed of a ferromagnetic material, but the free layer 130 has a changeable spin or magnetic direction. The capping layer 140 can serve to isolate the pMTJ cell 100 from outside conditions and can include more than one layer (see e.g., capping layers of FIG. 3B).

One of the more interesting physical features of pMTJs is that the cell 100 can experience variable resistance based on the directions of the reference ferromagnetic layer 110 and the free layer 130. If the reference ferromagnetic layer 110 and the free layer 130 are aligned in the same direction, the cell 100 can offer low resistance. Otherwise, the cell 100 can offer high resistance. As described in more detail with respect to FIGS. 3A and 3B, in accordance with embodiments of the subject invention, the free layer 130 is implemented with multiple layers to function as a single magnetic layer that can be used to optimize the pMTJ for various applications.

One promising application of MTJ technology is as a form of memory as magnetoresistance random-access memory, using the two distinct states to represent one and zero, and since the states are determined by magnetic fields rather than current, the stored values are considered non-volatile insofar as they maintain state even without power. MTJ memory cells also offer high speeds for reading and writing – especially reading, as the voltage value can simply be read to determine the content.

FIG. 2 illustrates an array of pMTJ cells arranged in for memory application. A group of pMTJ cells can be arranged in a variety of architectures - generally speaking, cells can be arranged in a great number of ways, one of which is shown here. A series of MTJ cells 100 can be arranged in a row, connected by a bit line 210 and a power line 220. The bit line 210 can allow the memory cell to be read by taking the voltage at that spot as the voltage read by a particular cell would vary depending on whether the two magnetic portions of have their magnetic fields parallel or antiparallel. The power line 220 can provide a reference voltage that allows the bit line 210 to read the particular cell. In some cases, the power line 220 can also provide read or write functionality.

When selecting materials to compose the pMTJ cells for application in memory, there are a number of goals that are worth considering. While non-volatility is generally a property intrinsic to pMTJs, size, speed, endurance, power consumption, and resolution between ones and zeroes are all factors that can vary notably based on materials. As mentioned above, through using a multi-interface free layer, the characteristics of the pMTJ can be optimized for a particular application and allow a combination of factors to be prioritized.

FIGS. 3A and 3B illustrate example configurations of a pMTJ with a multi-interface free layer (MIFL). Referring to FIG. 3A, as described with respect to the primary structure of a pMTJ shown in FIG. 1, a pMTJ cell 300, includes a reference ferromagnetic layer 302, a barrier layer 304 on the reference ferromagnetic layer 302, and a capping layer 306 at a terminal end of the pMTJ 300. As mentioned above, instead of a single free layer, pMTJ cell 300 includes a MIFL 310 on the barrier layer 304 and under the capping layer 306.

The MIFL 310 includes at least three coupled sublayers. The at least three coupled sublayers include a first sublayer 312 and other sublayers (e.g., sublayer 314 and sublayer 316). The other sublayers (e.g., sublayer 314 and sublayer 316) on the first sublayer 312 are formed of at least one different material than the first sublayer.

For example, the at least three coupled sublayers are formed of at least two materials. The sublayers can alternate between ferromagnetic and nonmagnetic layers; however, embodiments are not limited thereto. The number of sublayers of the MIFL may be constrained by the physics of the materials (e.g., the minimum thickness of each layer to still provide appropriate functionality and the total thickness of the free layer). In some cases, the total thickness may be 10-15 nm, where the thickness of each sublayer is between 0.5 nm and 2 nm. Ideally, for any pMTJ at a given lateral size, the number of ferromagnetic layers and therefore the total number of interfaces (N) contributing to PMA energy density can be increased until the desired thermal stability factor is reached.

The sublayers are “coupled,” meaning that the various layers in the MIFL act as a single free layer or single magnetic unit. In other words, in normal operation, all sublayers of the coupled sublayers will serve coherently as a whole. The coupling can be either ferromagnetically coupled (FM) or antiferromagnetically coupled (AF), depending on specific design goals and can be controlled by the materials and thickness of the ferromagnetic and nonmagnetic layers, as well as post-fabrication processes such as thermal annealing. As described in more detail with respect to the experimental examples, the first sublayer in the MIFL most heavily contributes to the tunneling magnetic resistance (TMR) by a reasonable amount and therefore, selection of the first sublayer can be used to control characteristics relevant to the TMR.

As such, the first sublayer can be a ferromagnetic material, such as CoFeB. FIG. 3B shows a schematic representation of a pMTJ cell 350 with MIFL 360 using CoFeB as a first sublayer 362. In the illustrated representation, pMTJ cell 350 has a MIFL 360 with at least 6 layers (and N ≥ 6, including the interface between the first sublayer 362 and the MgO barrier layer).

The first sublayer can be thicker than the other sublayers in the MIFL. For example, the first sublayer can be between 0.8 nm and 1.7 nm thick, such as 1.5 nm thick, while other sublayers of the MIFL can be 0.5 nm to 1 nm thick. The first sublayer can be specifically chosen to maximize tunneling magnetic resistance (TMR) to increase contrast between a value of zero and a value of one in memory.

Other sublayers of the MIFL can be composed of at least one other material. In most cases, the at least one other material should include at least one nonmagnetic material. In some cases, sublayers can alternate between ferromagnetic and nonmagnetic materials. In the case where a MIFL includes at least two nonmagnetic sublayers, the at least two nonmagnetic sublayers can be composed of the same or different nonmagnetic materials. Since the first sublayer is most influential in creating contrast (between the value of zero and the value of one in memory), the other sublayers of the MIFL can be selected to optimize other characteristics, such as high switching speed. Example magnetic materials of the first sublayer (and some of the other sublayers) can include CoₓFe_{y}B_{z} (x,y,z are atomic parentages ranging from 0-100% and x+y+z =100%), Co, Fe, Ni or their alloys, CoPd, CoPt, and Heusler alloys such as CoMnSi. Example nonmagnetic materials of the sublayers can include MgO, Ta, Mo, Ir, W, Ru, Pt, Pd and Hf.

The following provides results of experiments showing the benefits of the described MIFL structure. The films evaluated in the following experiments were fabricated in a 12-source UHV sputtering system (AJA International) with a base pressure of 10⁻⁷ Pa (10⁻⁹ Torr). The structure of the MTJ films is Si/SiO₂/Ta(12 nm)/Ru(15 nm)/Ta(10 nm)/Mo (0.75 nm)/Co₂₀Fe₆oB₂₀(1 nm)/MgO(1.5-3.5 nm)/MIFL/Mo (1.9 nm)/Ta(10 nm)/Ru(20 nm). Different MIFL film compositions were synthesized as detailed below. Circular pMTJs with diameters ranging from 2 µm to 100 µm were patterned by conventional microfabrication process involving photolithography and ion beam etching, and subsequently annealed under varying conditions.

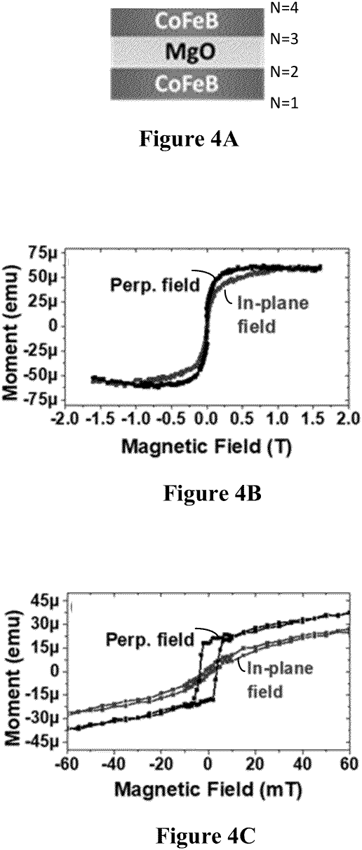

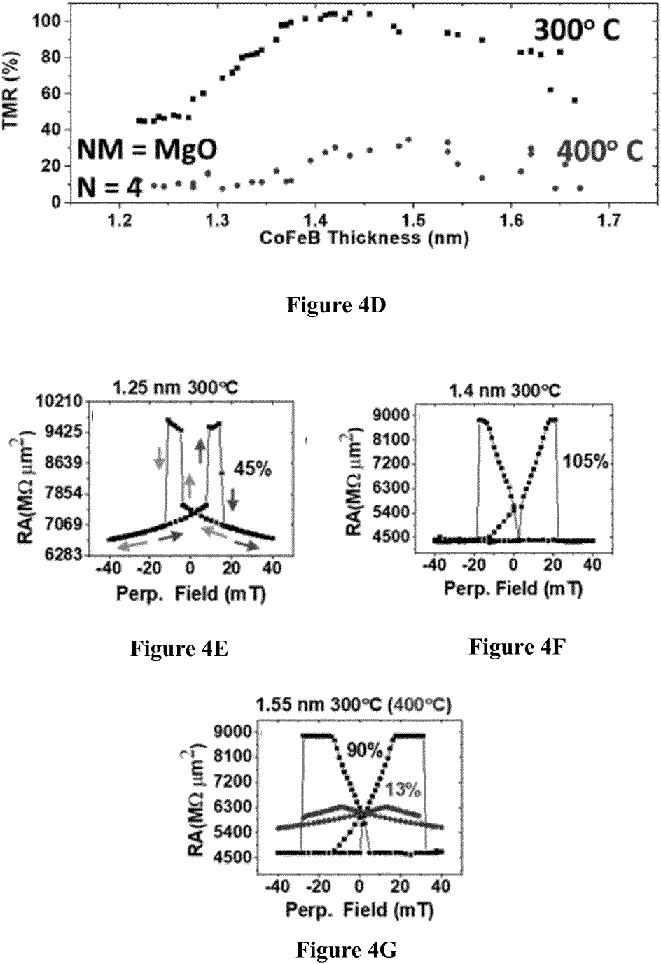

FIG. 4A shows a representation of a MIFL having N= 4 and alternating sublayers of CoFeB and MgO. FIGS. 4B-4G shows experimental results for MIFLs with MgO as the coupling layer. FIG. 4B shows Hysteresis loops of [CoFeB(0.75 nm)/MgO(0.8 nm)]₃ measured under different magnetic fields. FIG. 4C shows the same curves at the low-field region. FIG. 4D shows CoFeB thickness dependence of the TMR in pMTJs with MgO-MIFLs such as shown in FIG. 4A. The samples were first annealed at 300° C. for 10 min, then 400° C. for another 10 min. FIGS. 4E, 4F, and 4G show representative TMR curves of the pMTJs having 1.25 nm, 1.4 nm, and 1.55 nm MgO thicknesses, respectively, after the 300° C. annealing. The arrows in FIG. 4D show the representative magnetic field sweeping direction [one set move from left to right towards the positive field direction and the other set of arrows move from right to left in the negative field direction]. The curve labeled 13% in FIG. 4G is the TMR of the same 1.55 nm sample after the 400° C. annealing.

In addition to the larger TMR, the CoFeB/MgO interface also provides a strong interfacial perpendicular magnetic anisotropy (PMA). It can be desirable to have a MgO coupling layer that is thick enough to support a strong coupling, but thin enough to contribute only minimal additional series resistance to the overall resistance of the pMTJ – which may be satisfied if current can conduct across pinholes within the thin MgO layer. The magnetic properties of the MIFL with MgO was first investigated in a sample with the structure of [CoFeB(0.75 nm)/MgO(0.8 nm)]₃ by a vibrating sample magnetometer (VSM). The film, which includes three CoFeB layers and three MgO layers, exhibits PMA as shown in FIG. 4B, where an in-plane anisotropy field larger than 1 T (10 kOe) can be observed. The MH loops in the low field region is shown in FIG. 4C, where the remanent magnetic moment is about 20 nA·m² (20 µemu) which is about one-third of the saturation moment (60 nA·m²), indicating the three CoFeB layers of the MgO-MIFL structure are AF-coupled.

Next, pMTJs with MIFLs of the structure, arranged as shown in FIG. 4A, of CoFeB (1.2 nm - 1.7 nm)/ MgO (0.9 nm)/CoFeB (1.3 nm) were fabricated and studied. These pMTJs are denoted as N=4 because the total PMA originates from three CoFeB/MgO interfaces and one CoFeB/Mo interface (recall the capping layers are Mo/Ta/Ru). Since the first CoFeB in the MIFL is the one contributing to both TMR and PMA, it is critical to study the thickness dependence of this layer. The TMR of these junctions after annealing at 300° C. for 10 min is plotted in FIG. 4D. The TMR is about 45% when CoFeB is 1.25 nm thick (FIG. 4E), which increases to more than 100% when CoFeB is 1.45 nm thick (FIG. 4F). Further increase of CoFeB thickness beyond this point leads to a slight decrease of TMR (FIG. 4G). The TMR is, however, reduced across the entire thickness series when the same pMTJs were annealed again (after testing at room temperature) at 400° C. for 10 min.

A number of processes simultaneously occur during the annealing process, most importantly the formation of the CoFe(001)/MgO(001) epitaxial structure with the B diffusing out of CoFeB, and the reduction of interfacial oxidation which eventually leads to proper hybridization of Oxygen 2p orbitals and Fe/Co 3d orbitals that is required for a strong PMA. Typically, the parallel state resistance (RP) of the junction momentarily drops at the beginning of the annealing, resulting from the initial establishment of the highly conductive Δ1 channel, followed by a steady increase due to the gradual deterioration of that channel when other atomic species inevitably diffuse into the barrier. Despite the increase of RP, the TMR may continue to increase at 400° C. for up to a few hours of annealing, provided that increases in the anti-parallel state resistance (RAP) due to the reduction of the Δ2 and Δ5 conduction channels outpaces of the increase of RP.

The comparison of the TMR curves from the same junction after annealing at 300° C. and 400° C. is presented in FIG. 4G. In addition to the increase of RP, RAP can be seen to decrease as shown by the red TMR curve. The decrease of RAP in FIG. 4G is accompanied by the disappearance of the sharp switching in the TMR curve, which is likely due to the reduction of PMA of the MIFL, instead of a more transport-intrinsic reason that is usually only expected when the annealing is much longer. The reduction of PMA might be a result of Boron aggregation at the CoFeB/MgO interface in the absence of any “Boron-absorbing” layer adjacent to the CoFeB layer.

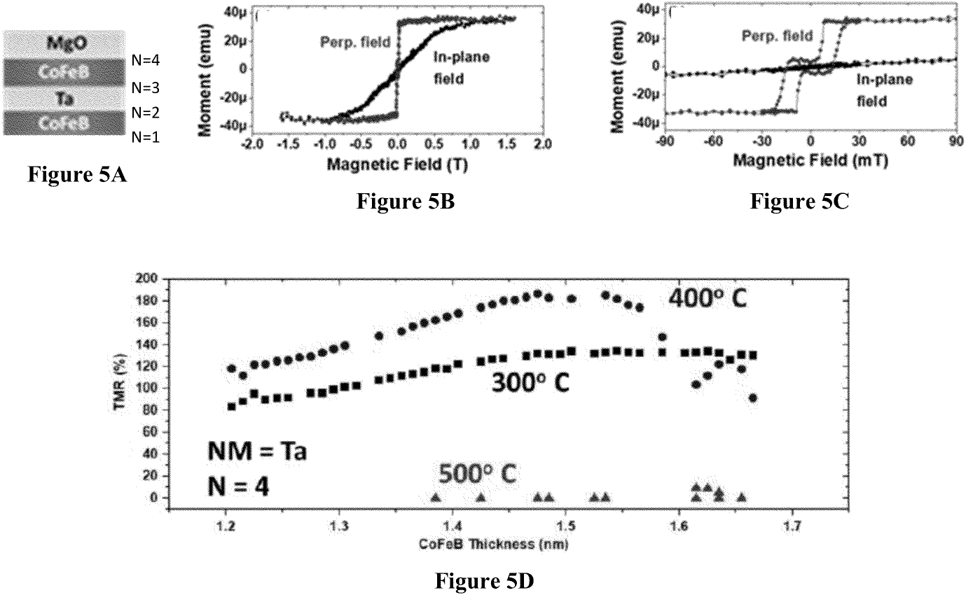

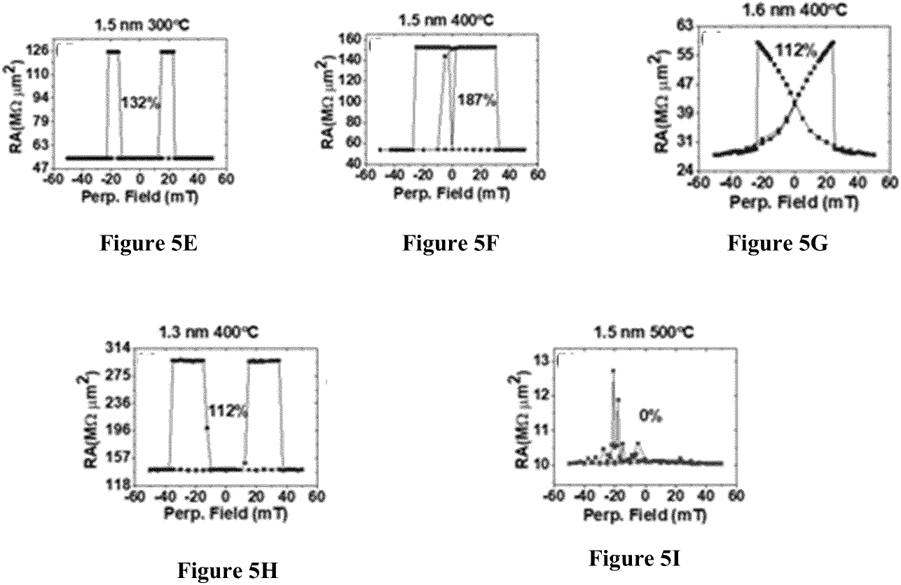

FIG. 5A shows a representation of a MIFL having N = 4 and alternating sublayers of CoFeB and Ta (referred to as Ta-MIFL). FIGS. 5B-5I show experimental results of performance of an MIFL of the structure of CoFeB/Ta/CoFeB, as shown in FIG. 5A. FIG. 5B shows hysteresis loops of MgO/ CoFeB/Ta(1 nm)/CoFeB/MgO measured on different magnetic fields. FIG. 5C shows the same curves at low field-region. FIG. 5D shows CoFeB thickness dependence of the TMR in pMTJs with Ta-MIFLs. The samples were successive annealed at each temperature for 10 min. FIG. 5E shows a TMR curve of the 1.5 nm sample after the 300° C. annealing. FIGS. 5F, 5G, and 5H show TMR curves of three pMTJs after the 400° C. annealing. FIG. 5I shows the TMR of the 1.5 nm sample after the 500° C. annealing.

Here, the structure CoFeB (1.2 nm-1.7 nm)/ Ta(1 nm)/CoFeB (1 nm)/MgO (0.8 nm) was investigated. For this MIFL structure there are two CoFeB/MgO interfaces and two CoFeB/Ta interfaces that each contribute to PMA. Maximum AF-coupling was observed in Co/Ta superlattices when Ta is near 0.7 nm. For CoFeB/Ta/CoFeB, a sizable AF coupling was obtained when the thickness of Ta is around 1 nm, which is in agreement with VSM results shown in FIGS. 5B and 5C. After 300° C. annealing for 10 min, maximal TMR of 135% was obtained as shown in FIG. 5D, which is considerably better in those shown in FIG. 4D. Reasonably high TMR (> 100 %) is present in pMTJs across a wide range of CoFeB thickness. A representative TMR curve for a first sublayer of CoFeB of 1.5 nm under a 300° C. annealing condition is shown in FIG. 5E, with sharp transitions between states and a clear AP state. This improved TMR behavior is likely related to the fact that the Ta coupling layer more readily absorbs Boron diffusing out from the CoFeB layer, compared to a MgO coupling layer. Subsequent annealing of these pMTJs at 400° C. for 10 min substantially increased the maximum TMR to above 180 % as shown in FIG. 5F, which is noticeably higher than previous reports. However, the TMR starts to fall off after the CoFeB thickness exceeds 1.5 nm and exhibits large fluctuations when CoFeB is thicker than 1.6 nm, as shown in FIG. 5G. This reduction in the TMR is attributed to the loss of the AP state as is shown in FIG. 5G. For comparison, FIG. 5H shows a representative TMR curve for a first sublayer of CoFeB of 1.3 nm under a 400° C. annealing condition.

Usually, the strength and sign of the interlayer coupling is sensitively depended on the thickness of the ferromagnetic and nonmagnetic layers. Here another complexity is involved, which is the PMA of MIFL. Due to the relatively small formation energy between Ta and Fe, it is known that the PMA of MgO/CoFeB/Ta is not stable when annealed at 400° C., which leads to the deterioration of PMA of the MIFL stack. Further annealing of these pMTJs at 500° C., as shown in FIG. 5I, leads to a dramatic reduction of TMR to nearly zero, consistent with previous studies.

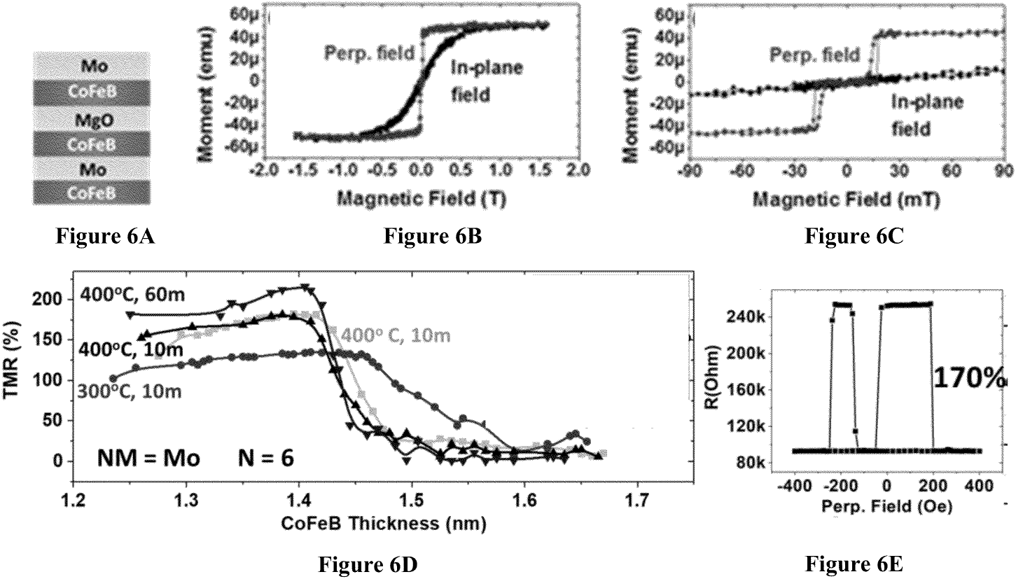

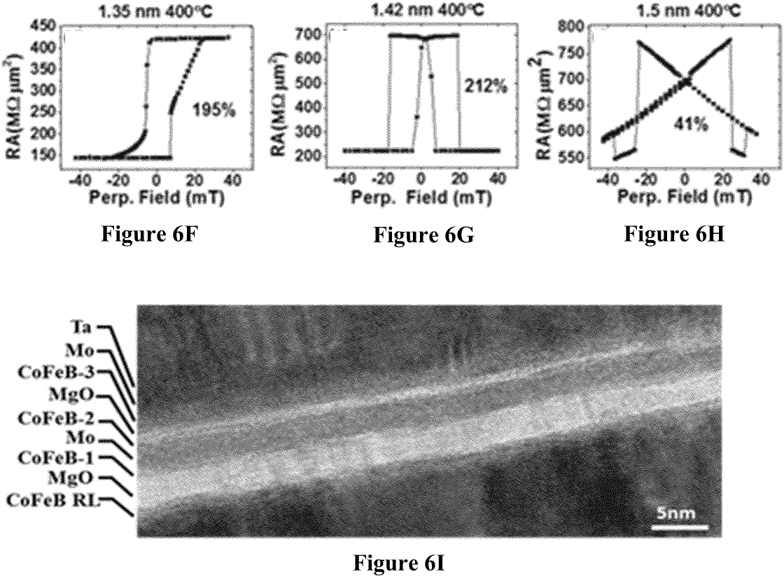

FIG. 6A shows a representation of a MIFL having N = 6 with sublayers of CoFeB, Mo, and MgO (referred to as Mo-MIFL). FIGS. 6B-6H show experimental results of performance of an MIFL of the structure of CoFeB/Mo/CoFeB/MgO/CoFeB as shown in FIG. 6A. FIG. 6B shows Hysteresis loops of MgO / CoFeB / Mo(0.9 nm) / CoFeB / MgO / CoFeB /Mo measured on different magnetic fields. FIG. 6C shows the same curves at low field-region. FIG. 6D shows a plot of CoFeB thickness dependence of the TMR in pMTJs with Mo-MIFLs. The samples with Mo-0.9 nm coupling layer were successive annealed at 300° C. for 10 min (dots), 400° C. for 10 min (up-pointing triangles), then 400° C. for another 50 min (down-pointing triangles, where the total annealing time at 400° C. is 60 min). The square data points are the TMR values of the samples with the Mo-1 nm coupling layer, annealed at 400° C. for 10 min. The lines are for guiding eyes only. FIG. 6E shows the TMR curve of a pMTJ with the Mo-1 nm coupling layer. FIGS. 6F, 6G, and 6H show representative TMR curves of three pMTJ after the 400° C. annealing for 60 min. FIG. 6I shows an HRTEM image of the pMTJ with MIFL as shown in FIG. 6A.

A benefit of Mo as a nonmagnetic layer for a MIFL is that its interlayer exchange coupling energy is larger compared to that of Ta. Mo can also substantially enhance damping. In this experiment, pMTJs with three CoFeB layers in the MIFL were fabricated. The MIFL stack structure is CoFeB (1.2 nm-1.7 nm)/Mo (0.9 nm)/ CoFeB (1 nm)/MgO(0.9 nm)/ CoFeB (1.3 nm), as represented by FIG. 6A. These samples are denoted as N=6 with Mo as plotted in FIG. 6D. The VSM results show the strong AF coupling for Mo(0.9 nm) are presented in FIG. 6B and FIG. 6C. The TMR ratios of the samples after annealing at 300° C. for 10 min (300° C., 10 m) (curve connecting circles) are presented in FIG. 6D. The maximum TMR in pMTJs with Mo-MIFL is similar to that of Ta-MIFL under this annealing condition.

However, as can be seen in FIG. 6D, the TMR starts to decay in pMTJs with Mo-MIFL when CoFeB is thicker than 1.5 nm. By comparison, the TMR with Ta-MIFL gains a slight increase over 1.5 nm to 1.6 nm under the same annealing condition as shown in FIG. 5D. This feature of Mo-MIFL becomes more pronounced after the annealing at 400° C. for 10 min (400° C., 10 m) as shown in the curve connecting upward triangles of FIG. 6D, where TMR drops sharply when CoFeB is thicker than 1.4 nm. When the pMTJs are annealed at 400° C. for one hour (400° C., 60 m), the overall TMR has been increased (curve connecting downward triangles), with maximum TMR reaching 212 % as shown in FIG. 6G, which is even higher than the TMR in pMTJs obtained previously with a single CoFeB layer as the free layer. However, TMR quickly drops when CoFeB thickness exceeds 1.42 nm. The reduction of TMR is again related to the disappearance of the AP state as shown in the FIG. 6H, which is likely due to the loss of PMA of the MIFL. These results highlight the very sensitive dependence of TMR on the first CoFeB layer thickness in the MIFL. The AF coupling peak with Mo varies in different reports, ranging from 0.5 nm to 0.8 nm.

In another series of pMTJ where the Mo in the MIFL is slightly thicker (1 nm), a more pronounced AF coupling of the free layer can be seen as shown in FIG. 6E. The free layer switching fields are obviously not symmetric about the zero magnetic field, which is a signature of the AF coupling of the CoFeB in the MIFL. The behavior of these pMTJs is plotted in the curve connecting squares (400° C., 10 m) in FIG. 6D. Interestingly, the range of CoFeB thicknesses where high TMR ratio is observed is extended by nearly 0.1 nm, as evident from the shift of the green curve relative to the black one.

The microstructure of pMTJ with Mo(0.6 nm) -MIFL was investigated by a tunneling electronic microscope and is presented in FIG. 6I. The MgO tunnel barrier exhibits good (001) crystalline structure throughout the specimen. The CoFeB reference layer beneath the MgO tunnel barrier and the first CoFeB in the MIFL show predominantly (001) texture, indicating successful solid-state-epitaxy from the MgO barrier outward during the 400° C. anneal. The successful recrystallization of the CoFeB/MgO/CoFeB complex is critical for the high TMR ratios observed within these pMTJs. The second and the third CoFeB layers in the MIFL, however, are only partially crystallized. The MgO layer in the MIFL is mostly continuous and exhibits partial crystallization from the thermal processing. Note in MIFLs the amorphous second (and third) CoFeB and some pinholes in the MgO could potentially be advantageous, as they may help to reduce the Gilbert damping and the resistance-area product of the devices, respectively. Note for Ta-MIFL with N=6, the maximum TMR is only 180%, again demonstrating the advantage of Mo as a useful HM layer.

These results suggest the first CoFeB thickness is significant for achieving the largest TMR in pMTJs with MIFL. Though the drop of TMR after a certain threshold thickness of the first CoFeB is a common feature observed in all three types of MIFLs in the experiments, the decay in pMTJs with Mo-MIFL is most pronounced. This phenomenon appears to be related to the reduced PMA of the first CoFeB layer when its thickness is getting larger. The presence of interlayer coupling makes the situation more complicated, which can certainly have a large influence on the switching behavior of the CoFeB layers in the MIFL. In particular, the coupling strength may vary with the thickness of the ferromagnetic layer, which in the Bruno model is due to the Fabry-Perot-type interferences of the electron wave functions through multiple reflections in ferromagnetic layers. Meanwhile, the magnetic properties of the CoFeB itself at a given thickness is under constant change (such as crystallization and redistribution of O at the MgO/CoFeB interface) when annealed at different conditions, which will in turn impact the interlayer magnetic coupling. The difference of the two sets of Mo-MIFL samples (0.9 nm vs 1 nm) also indicates the range of CoFeB thickness that gives rise to high TMR may be expanded if the AF coupling is enhanced.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

What is claimed is:

1. A magnetic memory cell comprising:
a reference ferromagnetic layer;
a barrier layer on the reference ferromagnetic layer;
a multiple-interface free layer (MIFL) on the barrier layer, wherein the MIFL comprises at least three coupled sublayers, wherein the at least three coupled sublayers comprise a first sublayer and at least two other sublayers, wherein the at least two other sublayers on the first sublayer include at least one different material than the first sublayer; and
a capping layer on the MIFL.

2. The magnetic memory cell of claim 1, wherein the first sublayer comprises a ferromagnetic material.

3. The magnetic memory cell of claim 2, wherein the ferromagnetic material comprises CoFeB.

4. The magnetic memory cell of claim 2, wherein the at least two other sublayers include a nonmagnetic material.

5. The magnetic memory cell of claim 4, wherein the nonmagnetic material comprises MgO.

6. The magnetic memory cell of claim 4, wherein the nonmagnetic material comprises Ta.

7. The magnetic memory cell of claim 4, wherein the nonmagnetic material comprises Mo.

8. The magnetic memory cell of claim 4, wherein the nonmagnetic material comprises Ru.

9. The magnetic memory cell of claim 2, wherein the at least two other sublayers include at least one sublayer of a first nonmagnetic material and at least one sublayer of a second nonmagnetic material.

10. The magnetic memory cell of claim 9, wherein the first nonmagnetic material is Mo and the second nonmagnetic material is MgO.

11. The magnetic memory cell of claim 1, wherein the first sublayer has a thickness of 0.8 nm - 1.7 nm.

12. The magnetic memory cell of claim 11, wherein the first sublayer has a thickness of 1.4 nm - 1.6 nm.

13. The magnetic memory cell of claim 11, wherein the at least two other sublayers each have a corresponding thickness of 0.5 nm - 1 nm.

14. The magnetic memory cell of claim 1, wherein the MIFL is antiferromagnetically coupled.

15. The magnetic memory cell of claim 1, wherein the MIFL is ferromagnetically coupled.

16. The magnetic memory cell of claim 1, wherein the first sublayer is selected for optimizing contrast between a value of zero and a value of one for memory and the other sublayers are selected for optimizing high switching speed.
